(19) United States
(12) Patent Application Publication
(10) Pub. No.: US 2014/0057054 A1
(43) Pub. Date: Feb. 27, 2014

(54) CO-EVAPORATION ALLOY MATERIAL AND EVAPORATION COATING METHOD USING THE SAME

(71) Applicants: SHENZHEN FUTAIHONG PRECISION INDUSTRY CO., LTD., (US); FIH (HONG KONG) LIMITED, Kowloon (HK)

(72) Inventor: DA-HUA CAO, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/869,702

(22) Filed: Apr. 24, 2013

(30) Foreign Application Priority Data
Aug. 21, 2012 (CN) 2012102973567

(51) Int. Cl. C23C 14/14; B32B 15/01

(52) U.S. Cl. CPC C23C 14/14; B32B 15/01; B32B 15/017
USPC 427/457; 428/686; 428/646; 428/647; 428/651; 428/649

(57) ABSTRACT

A co-evaporation alloy material includes a first evaporation material and a second evaporation material, the first evaporation material being completely covered by the second evaporation material. The second evaporation material is a metal or metal alloy different from the first evaporation material. The melting point of the first evaporation material is lower than the melting point of second evaporation material. An evaporation coating method using the co-evaporation alloy material is also provided.

### BACKGROUND

1. Technical Field

The present disclosure relates to a co-evaporation alloy material and an evaporation coating method using the co-evaporation alloy material.

2. Description of Related Art

Evaporation using signal crystal metal(s) with high purity can produce coatings having a uniform composition. However, it can be difficult to produce a single crystal with high purity. To overcome the above problem, substrates are heated under high temperature and high vacuum condition during a traditional co-evaporation method. However, co-evaporation equipment that provides high temperatures under high vacuum conditions can be expensive. Also the substrates used in the co-evaporation method have a higher heat-resistant requirement to prevent substrates from being damaged by heat.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary co-evaporation alloy material and evaporation coating method using the co-evaporation alloy material. Moreover, in the drawings like reference numerals designate corresponding parts throughout the several views. Wherever possible, the same reference numbers are used throughout the drawings to refer to the same or like elements of an embodiment.

FIG. 1 is a cross-sectional view of an exemplary embodiment of a co-evaporation alloy material.

FIG. 2 is a schematic view of a vacuum evaporation coating machine.

### DETAILED DESCRIPTION

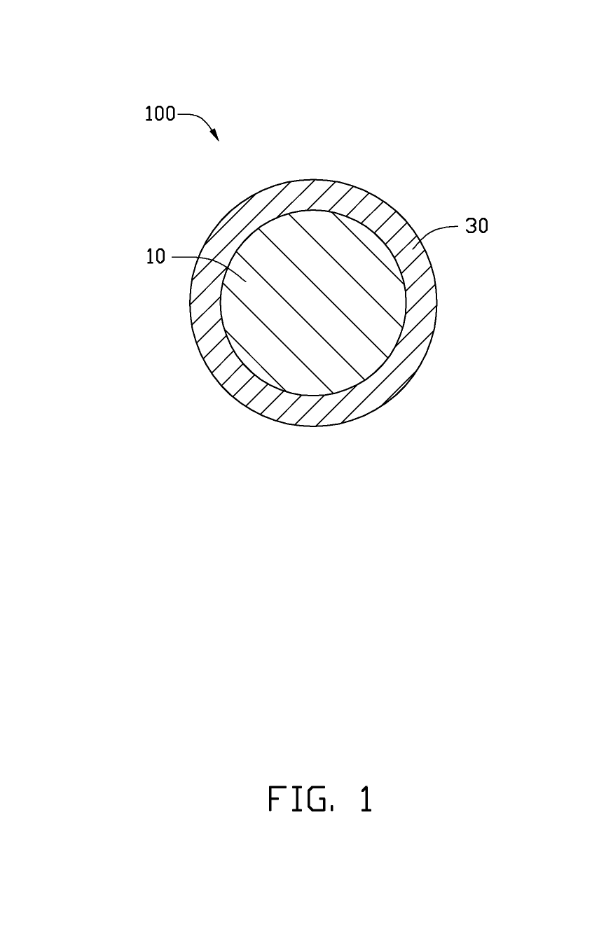

FIG. 1 shows an exemplary embodiment of a co-evaporation alloy material 100. The co-evaporation alloy material 100 is cylindrically shaped. The co-evaporation alloy material 100 includes a first evaporation material 10 and a second evaporation material 30. The first evaporation material 10 is completely covered by the second evaporation material 30. The melting point of the first evaporation material 10 is lower than the melting point of second evaporation material 30. The second evaporation material 30 is deposited on the first evaporation material 10 by electroplating, chemical plating or thermal spray coating.

The second evaporation material 30 and the first evaporation material 10 are made of different metals or metal alloys. The first evaporation material 10 includes at least one metal selected form the group of aluminum, copper and magnesium. The second evaporation material 30 may be made of chromium and/or tin.

The first evaporation material 10 is cylindrically shaped. The first evaporation material 10 has a diameter of about 0.5 mm to about 1 mm. The second evaporation material 30 has a thickness of about 100 micrometer (μm). The mass ratio of first evaporation material 10 and the second evaporation material 30 is about 3:1 to about 6:1.

In the embodiment, the first evaporation material 10 is aluminum; the second evaporation material 30 is chromium. The first evaporation material 10 has a diameter of about 0.5 mm. In the co-evaporation alloy material 100, when the first evaporation material 10 is aluminum having a diameter of about 0.5 mm and the second evaporation material 30 is chromium, the mass of the first evaporation material 10 is about 0.3579 g, the mass of the second evaporation material 30 is about 0.1159 g

In another embodiment, the first evaporation material 10 is aluminum; the second evaporation material 30 is chromium. The first evaporation material 10 has a diameter of about 1 mm. In the co-evaporation alloy material 100, when the first evaporation material 10 is aluminum having a diameter of about 1 mm and the second evaporation material 30 is chromium, the mass of the first evaporation material 10 is about 1.559 g, the mass of the second evaporation material 30 is about 0.2705 g.

An evaporation coating method using the co-evaporation alloy material 100 includes at least the following steps:

A substrate 11 is provided.

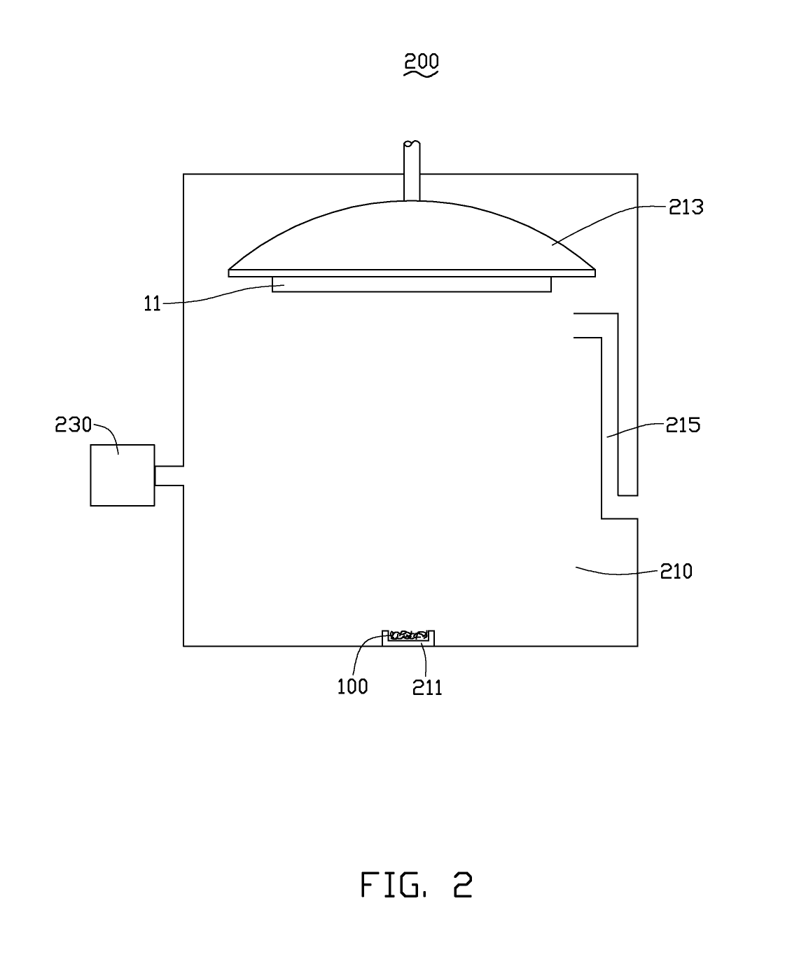

Referring to FIG. 2, a vacuum evaporation coating machine 200 is provided. The vacuum evaporation coating machine 200 includes a chamber 210 and a vacuum pump 230 connected to the chamber 210. The vacuum pump 230 is used to evacuate the chamber 210. The chamber 210 further includes an evaporator 211, a bracket 213 and a gas inlet 215. The evaporator 211 receives the co-evaporation alloy material 100.

The substrate 11 is retained on the bracket 213. The co-evaporation alloy material 100 is received in the evaporator 211. The chamber 210 is evacuated by the vacuum pump 230. Then, the evaporator 211 is turned on to heat the co-evaporation alloy material 100.

During the heating treatment, firstly, the voltage of the evaporator 211 is slowly increased until the second evaporation material 30 starts to melt; secondly, the voltage of the evaporator 211 is further increased to vaporize the co-evaporation alloy material 100 to form a coating having a uniform composition after the first evaporation material 10 and the second evaporation material 30 are completely melted.

In the embodiment, the first evaporation material 10 is aluminum; the second evaporation material 30 is chromium. The co-evaporation alloy material 100 is heated by the following steps: firstly, the voltage of the evaporator 211 is increased to about 3 volts (V)-4 V in about 10 seconds(s) to about 15 s to melt the chromium; secondly, the voltage of the evaporator 211 is kept constant for about 15 s to about 25 s to completely melt the chromium and aluminum; thirdly, the voltage of the evaporator 211 is increased from about 3 V-4 V to about 7 V-8 V in about 15 s-25 s to co-evaporate chromium and aluminum simultaneously.

During the evaporation coating process, the first evaporation material 10 is melted firstly. Since the second evaporation material 30 completely covered by the first evaporation material 10 is still un-melted, the melted first evaporation material 10 cannot vaporize and deposit on the substrate 11. When the second evaporation material 30 is completely melted, the first evaporation material 10 and the second evaporation material 30 are mixed to produce alloy melting bodies with a round shape. As the voltage of the evaporator 211 increase, the alloy melting bodies is co-evaporated and deposited on the substrate 11 to form coatings having a uniform composition.

Accordingly, coatings formed by the method have approximately same content composition as the co-evaporation alloy material 100 had. The method also can prevent the content of the first evaporation material 10 and/or the content of the second evaporation material 30 of the coatings from gradually changing as the evaporating time increase, thus providing coatings having a uniform composition.

The co-evaporation alloy material 100 is easy to prepare. The method using the co-evaporation alloy material 100 has a low vacuum requirement to the vacuum evaporation coating machine 200.

It is to be understood, however, that even through numerous characteristics and advantages of the exemplary disclosure have been set forth in the foregoing description, together with details of the system and function of the disclosure, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A co-evaporation alloy material comprising:
a first evaporation material, the first evaporation material being a metal or metal alloy; and
a second evaporation material, the first evaporation material being completely covered by the second evaporation material, the second evaporation material being a metal or metal alloy different from the first evaporation material, the melting point of the first evaporation material being lower than the melting point of second evaporation material.

2. The co-evaporation alloy material of claim 1, wherein the second evaporation material is deposited on the first evaporation material by electroplating, chemical plating or thermal spray coating.

3. The co-evaporation alloy material of claim 1, wherein the first evaporation material includes at least one metal selected form the group of aluminum, copper and magnesium.

4. The co-evaporation alloy material of claim 3, wherein the second evaporation material comprises chromium and/or tin.

5. The co-evaporation alloy material of claim 1, wherein the first evaporation material is cylindrically-shaped.

6. The co-evaporation alloy material of claim 5, wherein the first evaporation material has a diameter of about 0.5 mm to about 1 mm.

7. The co-evaporation alloy material of claim 5, wherein the second evaporation material has a thickness of about 100 μm.

8. The co-evaporation alloy material of claim 1, wherein the mass ratio of first evaporation material and the second evaporation material is about 3:1 to about 6:1.

9. The co-evaporation alloy material of claim 8, wherein the first evaporation material is aluminum, the second evaporation material is chromium.

10. The co-evaporation alloy material of claim 9, wherein in the co-evaporation alloy material, the mass of the first evaporation material is about 0.3579 g, the mass of the second evaporation material is about 0.1159 g.

11. The co-evaporation alloy material of claim 10, wherein the first evaporation material has a diameter of about 0.5 mm.

12. The co-evaporation alloy material of claim 9, wherein in the co-evaporation alloy material, the mass of the first evaporation material is about 1.559 g, the mass of the second evaporation material is about 0.2705 g.

13. The co-evaporation alloy material of claim 12, wherein the first evaporation material has a diameter of about 1 mm.

14. A evaporation coating method comprising:
providing substrates;
providing a co-evaporation alloy material, the co-evaporation alloy material comprising a first evaporation material and a second evaporation material, the first evaporation material being completely covered by the second evaporation material, the second evaporation material being a metal or metal alloy different from the first evaporation material, the melting point of the first evaporation material being lower than the melting point of second evaporation material;
providing a vacuum evaporation coating machine, the vacuum evaporation coating machine comprising a chamber and a vacuum pump connected to the chamber, the chamber comprising an evaporator and a bracket;
retaining the substrates on the bracket, positioning the co-evaporation alloy material in the evaporator, and evacuating the chamber by the vacuum pump;
heating the co-evaporation alloy material to melt the first evaporation material, then increasing voltage of the evaporator to completely melt the first evaporation material and the second evaporation material, and further increasing the voltage of the evaporator to vaporize the melted co-evaporation alloy material on the substrates.

15. The evaporation coating method of claim 14, wherein the first evaporation material includes at least one metal selected form the group of aluminum, copper and magnesium.

16. The evaporation coating method of claim 15, wherein the second evaporation material comprises chromium and/or tin.

17. The evaporation coating method of claim 14, wherein the first evaporation material is aluminum, the second evaporation material is chromium.

18. The evaporation coating method of claim 17, wherein the co-evaporation alloy material is heated by the following steps: firstly, the voltage of the evaporator is increased to about 3 V to about 4 V in about 10 s to about 15 s to melt the chromium; secondly, the voltage of the evaporator remains constant for about 15 s to about 25 s to completely melt chromium and aluminum; thirdly, the voltage of the evaporator is increased from about 3 V-4 V to about 7 V-8 V in about 15 s-25 s to co-evaporate chromium and aluminum simultaneously.
